(19) United States
(12) Patent Application Publication
(10) Pub. No.: US 2023/0030274 A1
(43) Pub. Date: Feb. 2, 2023

(54) Resistive Network Splitter for Enhanced Probing Solutions

(71) Applicant: Intel Corporation, Santa Clara, CA (US)

(72) Inventors: John R. Drew, Hillsboro, OR (US); Kari A. Wiborg, Hillsboro, OR (US)

(73) Assignee: Intel Corporation, Santa Clara, CA (US)

(21) Appl. No.: 17/957,409

(22) Filed: Sep. 30, 2022

(51) Int. Cl. H03H 7/38; G06F 3/06

(52) U.S. Cl. CPC H03H 7/38; G06F 3/0655; G06F 3/0673; G06F 3/0604

(57) ABSTRACT

Methods and apparatus relating to a resistive network splitter for enhanced probing solutions are described. In one embodiment, an interposer interface is coupled between a first component and a second component to allow a probe to capture one or more waveforms to be exchanged between the first component and the second component. A resistive network splitter couples the interposer interface to the probe and the second component and the resistive network comprises a plurality of resistors. Other embodiments are also claimed and disclosed.

### FIELD

The present disclosure generally relates to the field of electronics. More particularly, an embodiment relates to a resistive network splitter for enhanced probing solutions.

### BACKGROUND

Generally, a test probe is used to connect electronic test equipment to a device under test (DUT).

Real-time probing of analog signals frequently may at best produce an approximation of the true waveform, e.g., due to artificial reflections introduced by some probing solutions.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIG. 1 illustrates a block diagram of a resistive network splitter (R-Split) analog probing solution, according to an embodiment.

FIG. 2 illustrates sample scaled pulse responses for three probing solutions, according to some embodiments.

FIG. 3 illustrates sample scaled waveforms, according to some embodiments.

FIG. 4 illustrates a block diagram of an embodiment of a computing system, which may be utilized in various embodiments discussed herein.

FIG. 5 illustrates a block diagram of an embodiment of a computing system, which may be utilized in various embodiments discussed herein.

FIG. 6 illustrates various components of a processer in accordance with some embodiments.

### DETAILED DESCRIPTION

In the following description, numerous specific details are set forth in order to provide a thorough understanding of various embodiments. However, various embodiments may be practiced without the specific details. In other instances, well-known methods, procedures, components, and circuits have not been described in detail so as not to obscure the particular embodiments. Further, various aspects of embodiments may be performed using various means, such as integrated semiconductor circuits (“hardware”), computer-readable instructions organized into one or more programs (“software”), or some combination of hardware and software. For the purposes of this disclosure reference to “logic” shall mean either hardware (such as logic circuitry or more generally circuitry or circuit), software, firmware, or some combination thereof.

As mentioned above, real-time probing of analog signals frequently may at best produce an approximation of the true waveform, e.g., due to artificial reflections introduced by some probing solutions. Currently, the signals at both the device and probe are generally distorted. This distortion may be tolerated for some implementations. Alternatively, at the junction separating the probe and device paths, high-impedance resistors may be placed in series with a probe path. This approach may minimize distortion on the device path but may heavily distort the analog signal at the probe point. Hence, both of the above-mentioned approaches may still result in a heavily distorted signal at one or both of device and probe inputs. This provides in a validation solution which may behave moderately to significantly differently from an un-probed counterpart.

To this end, some embodiments provide a resistive network splitter for enhanced probing solutions. In an embodiment, an interposer interface is coupled between a first component (e.g., a Central Processing Unit (CPU) or processor) and a second component (e.g., a memory device) to allow a probe to capture one or more waveforms to be exchanged between the first component and the second component. A resistive network splitter couples the interposer interface to the probe and the second component. The resistive network comprises a plurality of resistors, where the value of each of the plurality of resistors is to be determined as a function of input and output transmission line impedances for the resistive network. At least one embodiment mitigates waveform distortion at both the probe and device by impedance-matching the split junction. This approach may nullify the most extreme (e.g., mid-bus) reflections.

While some embodiments may describe uses for memory devices, embodiments are also applicable for any probing solution applied to other components. Further, one or more embodiments may be useful for memory devices since memory implementations tend to utilize a relatively large bus with several single-ended signals. As a result, any other probing solution would take up a large amount of space and would have a particularly noticeable impact on the signal eye shape (e.g., given the added length and/or loading). However, any of the probes discussed herein, with reference to one or more embodiments, may utilize such probing solutions on any bus and for other types of components than just a memory device.

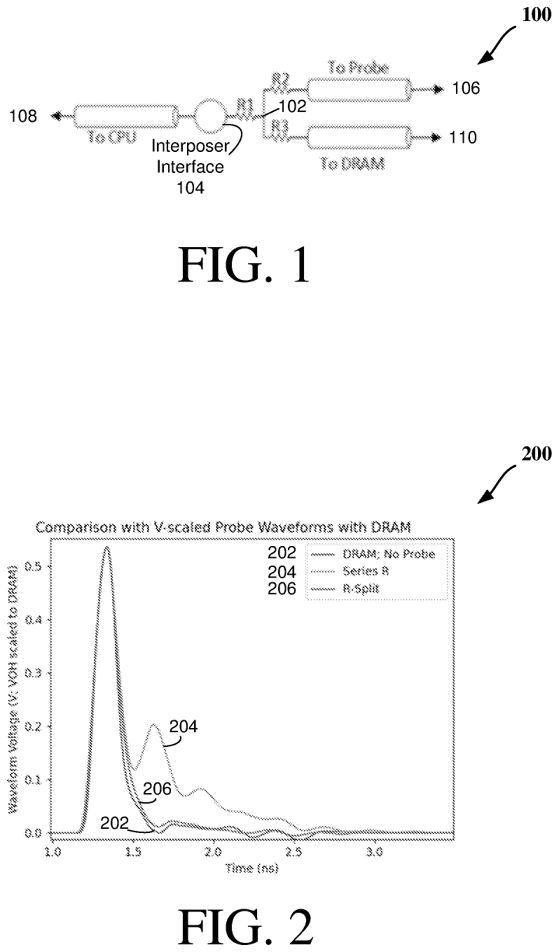

FIG. 1 illustrates a block diagram of a resistive network splitter (R-Split) analog probing solution 100, according to an embodiment. Generally, a baseline probing solution may employ a simple channel split, while the R-Split version implements a resistor tree (e.g., including resistors R1, R2, and R3) to mitigate reflection of an in-bound signal waveform.

As shown in FIG. 1, a three-resistor (one in, two out) network is used to balance the input impedance of one-in-two-out junctions 102 to reduce waveform-distorting reflections. The values of each resistor (R1/R2/R3) in the network is tuned as a function of input and output transmission line impedances to effectively negate the worst reflection-induced distortions, e.g., to produce a scaled-down/clean version of the analog signal under consideration.

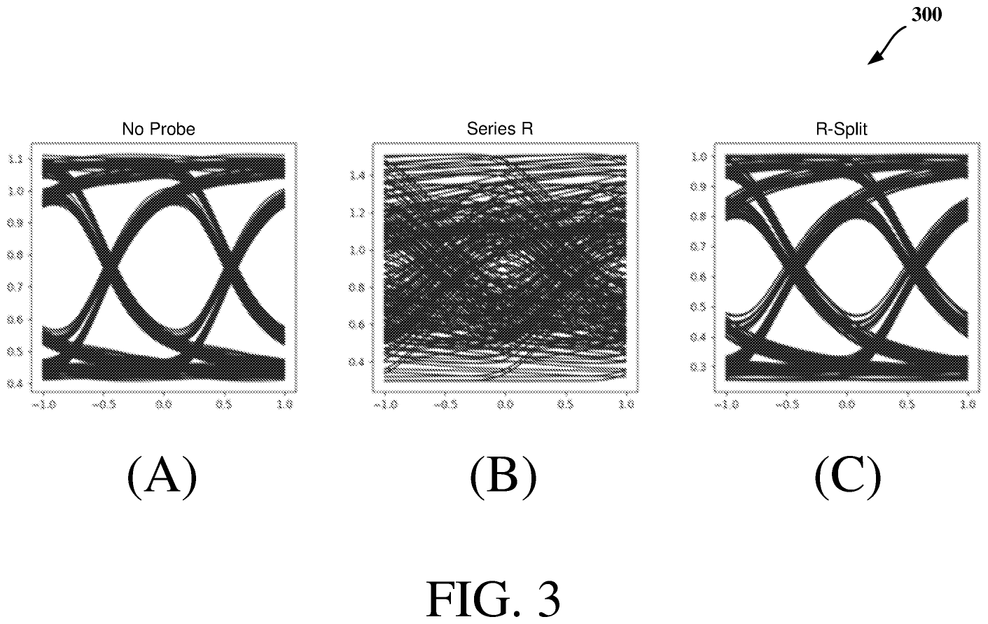

Implementation of such embodiments on probe cards may aid validation engineers in more faithfully reproducing analog waveforms at a probe point. This can in turn improve the ability of functional validation to accurately uncover and debug analog signal integrity risks on live platforms. Under near-marginal situations, the reproduced eye may match the original eye to within approximately a 20% error with respect to the prior solutions which may yield an entirely closed eye, see, e.g., the discussion of FIGS. 2 and 3.

In one embodiment, one or more of the resistors (R1/R2/R3) are surface-mount (SMT) resistors. Alternatively, embedded-resistor technology (e.g., within a stack-up of a probe) may be used to produce the resistors (R1/R2/R3).

Further, at least one embodiment utilizes a three-way resistor split implemented on validation probing solution (see, e.g., FIG. 1), e.g., as a solution for mitigating reflection-induced signal artifacts that may cause a probed waveform to differ substantially from the live waveform that the probed waveform is intended to reflect.

In one or more embodiments, the values of the resistors may be selected to match the Thevenin/equivalent resistance of the split path looking toward and into the split, per equations (1) and (2) (and assuming that each resistor uses the same value):

Z_{junction}=R+½(R+Zₒᵤₜ)= 3/2R+½Z, assuming Zᵢₙ=Zₒᵤₜ (1)

Assuming the targeted value of Z_{junction} is Z=Zᵢₙ=Zₒᵤₜ,

R=Z/3 (2)

In equations (1) and (2), “Z” denotes impedance and “R” denotes resistance. In various embodiments, this resistor split may be applied using standard SMT resistor packs or with printed resistors (assuming the probing solution's interposer interface 104 allows for it).

As discussed herein, a probing system may generally include (a) one or more interposers, where each interposer is designed to capture data traffic crossing a (e.g., card-connector or chip) interface, e.g., in the form of signals or waveforms; (b) one or more mid-bus probes, where each mid-bus probe is designed to capture traffic flowing between components on the same Printed Circuit Board (PCB) (such as a Central Processing Unit (CPU) or processor, memory (e.g., Dynamic Random Access Memory (DRAM)), etc.), e.g., through a pad designed into the PCB surface; and (c) one or more multi-lead probes which may be attached directly to expose traces on the PCB surface.

For example, in the R-Split probing solution of FIG. 1, the interposer interface 104 may allow a probe 106 to capture signals/data exchanged between the CPU/processor 108 and memory (e.g., DRAM, Double Date Rate (DDR) memory (including for example DDR2, DDR3, DDR4, DDR5, DDR6, etc. random access memory devices), etc.) 110. In one embodiment, the validation probing solution is implemented on a probe card coupled to a Peripheral Component Interface express (PCIe) bus, e.g., to allow for detection and collection of signal waveforms exchanged between computer components such as a CPU/processor, memory, etc. FIG. 2 illustrates sample scaled pulse responses 200 for three probing solutions, according to some embodiments. More specifically, the scaled pulse responses 200 are shown for baseline 202, Series R 204, and R-Split 206 scenarios/waveforms. The scaling factor may be determined by comparing ratios of effective termination.

Moreover, the scenarios shown in FIG. 2 are samples that may be tested on a memory (e.g., DRAM) platform according to some embodiments, e.g., at an approximate rate of 7.2 Gigabits per second (Gb/s). A native solution with no probe point may be selected as a baseline 202 to compare with a series R 204, and R-Split 206 probing solutions. It is assumed that the oscilloscope used may include the capability of scaling the probe waveform's voltage level to match the anticipated high-level output voltage (VOH) of the non-probe baseline, e.g., to compensate for the artificial voltage reduction due to parallel termination resistors at the probe point. Generally, a “VOH” refers to the voltage level at an output terminal with input conditions applied that, according to the product specification, would establish a high level at the output. As can be seen by reference to the example of FIG. 2, the R-Split waveform 206 more closely matches the base waveform 202 when compared with another scenario that may be used such as a series R waveform 204.

FIG. 3 illustrates sample scaled waveforms 300, according to some embodiments. The waveforms 300 may be pseudorandom binary sequence (PRBS) stimulated scaled waveforms. The waveforms in graphs (A) with no probe, (B) with series R, and (C) with R-Split represent samples with the same channel configurations discussed with reference to FIG. 2. As may be readily appreciated, the R-Split waveform lacks a large reflection that occurs in the Series R configuration. FIG. 3 shows the same waveforms as shown in FIG. 2 with the stimulation performed with a 256-bit PRBS waveform. Another sample 10,000-bit PRBS simulation to yield intersymbol interference (ISI) eye margins is listed in Table 1 below:

TABLE 1
Memory-Down 7200; ISI Only

| Configuration | ISI EH (mV) | ISI EW (UI) | Error: EH | Error: EW |
|---|---|---|---|---|
| DRAM (No Probe) | 366 | 0.857 | NA | NA |
| Probe (Series R) | 0 | 0 | 100 | 100 |
| Probe (Split-R) | 312 | 0.803 | 14.7541 | 6.30105 |

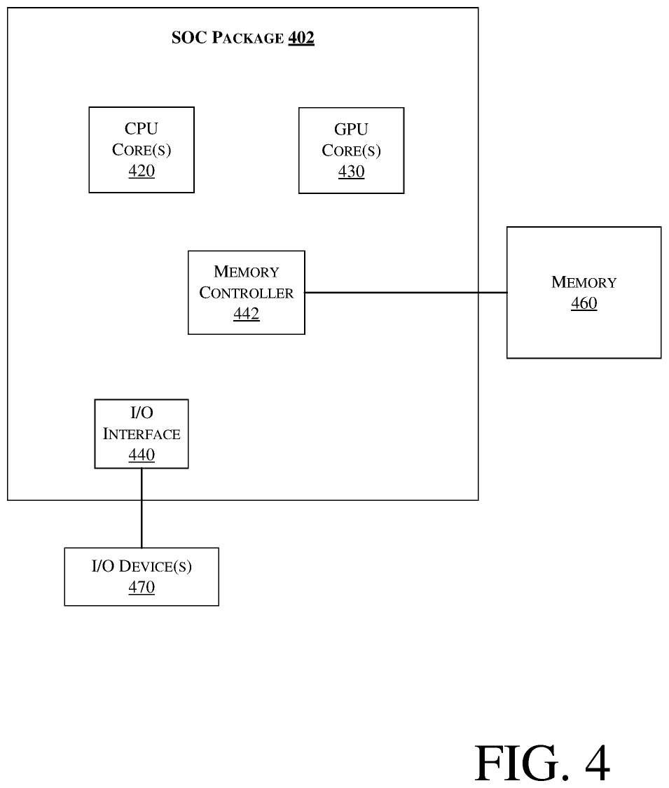

One or more components discussed with reference to FIGS. 4-6 (including but not limited to I/O devices, memory/storage devices, graphics/processing cards/devices, network/bus/audio/display/graphics controllers, wireless transceivers, etc.) may be probed/tested utilizing the techniques discussed above with reference to FIGS. 1-3. More particularly, FIG. 4 illustrates a block diagram of a System on Chip (“SOC” or “SoC”) package in accordance with an embodiment. As illustrated in FIG. 4, SOC 402 includes one or more Central Processing Unit (CPU) or processor cores 420, one or more Graphics Processor Unit (GPU) cores 430, an Input/Output (I/O) interface 440, and a memory controller 442. Various components of the SOC package 402 may be coupled to an interconnect or bus such as discussed herein with reference to the other figures. Also, the SOC package 402 may include more or less components, such as those discussed herein with reference to the other figures. Further, each component of the SOC package 420 may include one or more other components, e.g., as discussed with reference to the other figures herein. In one embodiment, SOC package 402 (and its components) is provided on one or more Integrated Circuit (IC) die, e.g., which are packaged into a single semiconductor device.

As illustrated in FIG. 4, SOC package 402 is coupled to a memory 460 via the memory controller 442. In an embodiment, the memory 460 (or a portion of it) can be integrated on the SOC package 402.

The I/O interface 440 may be coupled to one or more I/O devices 470, e.g., via an interconnect and/or bus such as discussed herein with reference to other figures. I/O device(s) 470 may include one or more of a keyboard, a mouse, a touchpad, a display, an image/video capture device (such as a camera or camcorder/video recorder), a touch screen, a speaker, or the like.

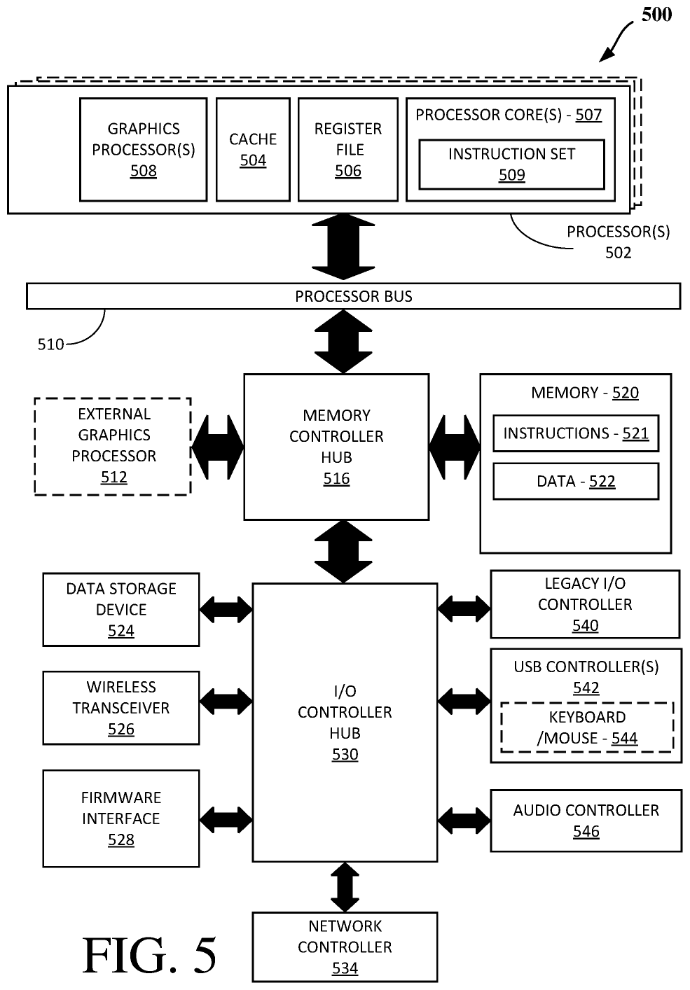

FIG. 5 is a block diagram of a processing system 500, according to an embodiment. In various embodiments the system 500 includes one or more processors 502 and one or more graphics processors 508, and may be a single processor desktop system, a multiprocessor workstation system, or a server system having a large number of processors 502 or processor cores 507. In an embodiment, the system 500 is a processing platform incorporated within a system-on-a-chip (SoC or SOC) integrated circuit for use in mobile, handheld, or embedded devices.

An embodiment of system 500 can include, or be incorporated within a server-based gaming platform, a game console, including a game and media console, a mobile gaming console, a handheld game console, or an online game console. In some embodiments system 500 is a mobile phone, smart phone, tablet computing device or mobile Internet device. Data processing system 500 can also include, couple with, or be integrated within a wearable device, such as a smart watch wearable device, smart eyewear device, augmented reality device, or virtual reality device. In some embodiments, data processing system 500 is a television or set top box device having one or more processors 502 and a graphical interface generated by one or more graphics processors 508.

In some embodiments, the one or more processors 502 each include one or more processor cores 507 to process instructions which, when executed, perform operations for system and user software. In some embodiments, each of the one or more processor cores 507 is configured to process a specific instruction set 509. In some embodiments, instruction set 509 may facilitate Complex Instruction Set Computing (CISC), Reduced Instruction Set Computing (RISC), or computing via a Very Long Instruction Word (VLIW). Multiple processor cores 507 may each process a different instruction set 509, which may include instructions to facilitate the emulation of other instruction sets. Processor core 507 may also include other processing devices, such a Digital Signal Processor (DSP).

In some embodiments, the processor 502 includes cache memory 504. Depending on the architecture, the processor 502 can have a single internal cache or multiple levels of internal cache. In some embodiments, the cache memory is shared among various components of the processor 502. In some embodiments, the processor 502 also uses an external cache (e.g., a Level-3 (L3) cache or Last Level Cache (LLC)) (not shown), which may be shared among processor cores 507 using known cache coherency techniques. A register file 506 is additionally included in processor 502 which may include different types of registers for storing different types of data (e.g., integer registers, floating point registers, status registers, and an instruction pointer register). Some registers may be general-purpose registers, while other registers may be specific to the design of the processor 502.

In some embodiments, processor 502 is coupled to a processor bus 510 to transmit communication signals such as address, data, or control signals between processor 502 and other components in system 500. In one embodiment the system 500 uses an exemplary ‘hub’ system architecture, including a memory controller hub 516 and an Input Output (I/O) controller hub 530. A memory controller hub 516 facilitates communication between a memory device and other components of system 500, while an I/O Controller Hub (ICH) 530 provides connections to I/O devices via a local I/O bus. In one embodiment, the logic of the memory controller hub 516 is integrated within the processor.

Memory device 520 can be a dynamic random access memory (DRAM) device, a static random access memory (SRAM) device, flash memory device, phase-change memory device, or some other memory device having suitable performance to serve as process memory. In one embodiment the memory device 520 can operate as system memory for the system 500, to store data 522 and instructions 521 for use when the one or more processors 502 executes an application or process. Memory controller hub 516 also couples with an optional external graphics processor 512, which may communicate with the one or more graphics processors 508 in processors 502 to perform graphics and media operations.

In some embodiments, ICH 530 enables peripherals to connect to memory device 520 and processor 502 via a high-speed I/O bus. The I/O peripherals include, but are not limited to, an audio controller 546, a firmware interface 528, a wireless transceiver 526 (e.g., Wi-Fi, Bluetooth), a data storage device 524 (e.g., hard disk drive, flash memory, etc.), and a legacy I/O controller 540 for coupling legacy (e.g., Personal System 2 (PS/2)) devices to the system. One or more Universal Serial Bus (USB) controllers 542 connect input devices, such as keyboard and mouse 544 combinations. A network controller 534 may also couple to ICH 530. In some embodiments, a high-performance network controller (not shown) couples to processor bus 510. It will be appreciated that the system 500 shown is exemplary and not limiting, as other types of data processing systems that are differently configured may also be used. For example, the I/O controller hub 530 may be integrated within the one or more processor 502, or the memory controller hub 516 and I/O controller hub 530 may be integrated into a discreet external graphics processor, such as the external graphics processor 512.

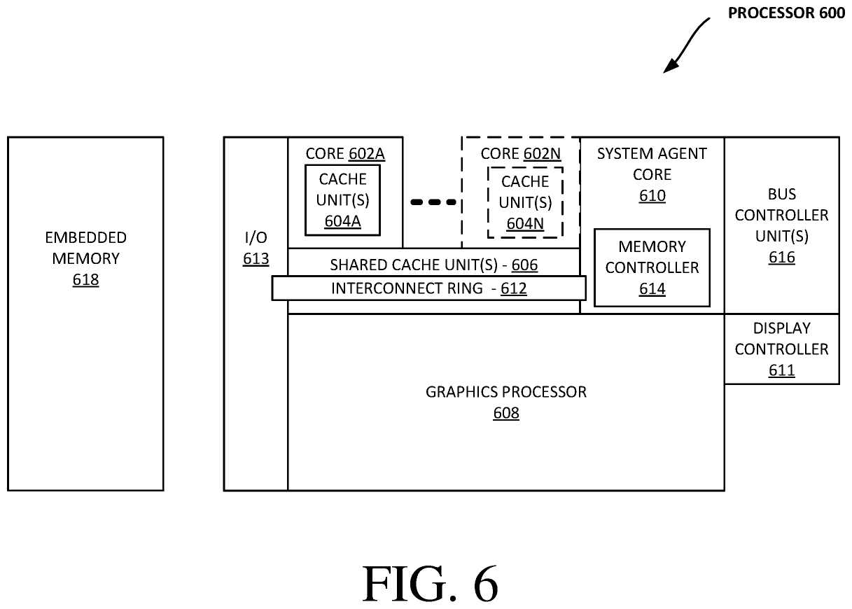

FIG. 6 is a block diagram of an embodiment of a processor 600 having one or more processor cores 602A to 602N, an integrated memory controller 614, and an integrated graphics processor 608. Those elements of FIG. 6 having the same reference numbers (or names) as the elements of any other figure herein can operate or function in any manner similar to that described elsewhere herein, but are not limited to such. Processor 600 can include additional cores up to and including additional core 602N represented by the dashed lined boxes. Each of processor cores 602A to 602N includes one or more internal cache units 604A to 604N. In some embodiments each processor core also has access to one or more shared cached units 606.

The internal cache units 604A to 604N and shared cache units 606 represent a cache memory hierarchy within the processor 600. The cache memory hierarchy may include at least one level of instruction and data cache within each processor core and one or more levels of shared mid-level cache, such as a Level 2 (L2), Level 3 (L3), Level 4 (L4), or other levels of cache, where the highest level of cache before external memory is classified as the LLC. In some embodiments, cache coherency logic maintains coherency between the various cache units 606 and 604A to 604N.

In some embodiments, processor 600 may also include a set of one or more bus controller units 616 and a system agent core 610. The one or more bus controller units 616 manage a set of peripheral buses, such as one or more Peripheral Component Interconnect buses (e.g., PCI, PCI Express). System agent core 610 provides management functionality for the various processor components. In some embodiments, system agent core 610 includes one or more integrated memory controllers 614 to manage access to various external memory devices (not shown).

In some embodiments, one or more of the processor cores 602A to 602N include support for simultaneous multi-threading. In such embodiment, the system agent core 610 includes components for coordinating and operating cores 602A to 602N during multi-threaded processing. System agent core 610 may additionally include a power control unit (PCU), which includes logic and components to regulate the power state of processor cores 602A to 602N and graphics processor 608.

In some embodiments, processor 600 additionally includes graphics processor 608 to execute graphics processing operations. In some embodiments, the graphics processor 608 couples with the set of shared cache units 606, and the system agent core 610, including the one or more integrated memory controllers 614. In some embodiments, a display controller 611 is coupled with the graphics processor 608 to drive graphics processor output to one or more coupled displays. In some embodiments, display controller 611 may be a separate module coupled with the graphics processor via at least one interconnect, or may be integrated within the graphics processor 608 or system agent core 610.

In some embodiments, a ring-based interconnect unit 612 is used to couple the internal components of the processor 600. However, an alternative interconnect unit may be used, such as a point-to-point interconnect, a switched interconnect, or other techniques, including techniques well known in the art. In some embodiments, graphics processor 608 couples with the ring interconnect 612 via an I/O link 613.

The exemplary I/O link 613 represents at least one of multiple varieties of I/O interconnects, including an on package I/O interconnect which facilitates communication between various processor components and a high-performance embedded memory module 618, such as an eDRAM (or embedded DRAM) module. In some embodiments, each of the processor cores 602 to 602N and graphics processor 608 use embedded memory modules 618 as a shared Last Level Cache.

In some embodiments, processor cores 602A to 602N are homogenous cores executing the same instruction set architecture. In another embodiment, processor cores 602A to 602N are heterogeneous in terms of instruction set architecture (ISA), where one or more of processor cores 602A to 602N execute a first instruction set, while at least one of the other cores executes a subset of the first instruction set or a different instruction set. In one embodiment processor cores 602A to 602N are heterogeneous in terms of microarchitecture, where one or more cores having a relatively higher power consumption couple with one or more power cores having a lower power consumption. Additionally, processor 600 can be implemented on one or more chips or as an SoC integrated circuit having the illustrated components, in addition to other components.

The following examples pertain to further embodiments. Example 1 includes an apparatus comprising: an interposer interface coupled between a first component and a second component to allow a probe to capture one or more waveforms to be exchanged between the first component and the second component; and a resistive network splitter to couple the interposer interface to the probe and the second component, wherein the resistive network comprises a plurality of resistors, wherein the plurality of resistors is to reduce signal reflection.

Example 2 includes the apparatus of example 1, wherein a value of each of the plurality of resistors is to be determined based at least in part on input and/or output transmission line impedances for the resistive network. Example 3 includes the apparatus of example 1, wherein the value of each of the plurality of resistors is to be determined as a function of input and out transmission line impedances to reduce signal reflections. Example 4 includes the apparatus of example 1, wherein the plurality of resistors comprises three resistors to form a three-way resistor split, wherein the value of each of the three resistors is to be determined to match an equivalent resistance of a split path looking toward and into the three-way resistor split. Example 5 includes the apparatus of example 1, wherein the plurality of resistors comprises a first resistor, a second resistor and a third resistor, wherein: the first resistor is to couple a resistive network junction to the first component, the second resistor is to couple the resistive network junction to the second component, and the third resistor is to couple the resistive network junction to the probe. Example 6 includes the apparatus of example 5, wherein the interposer interface is to couple the first component to a first end of the first resistor, wherein a second end of the first resistor is to couple to the resistive network junction. Example 7 includes the apparatus of example 1, wherein one or more of the plurality of resistors comprise a surface mount resistor or an embedded resistor. Example 8 includes the apparatus of example 1, wherein the first component comprises a processor having one or more processor cores.

Example 9 includes the apparatus of example 1, wherein the second component comprises a storage device. Example 10 includes the apparatus of example 9, wherein the storage device comprises a dynamic random access memory device. Example 11 includes the apparatus of example 9, wherein the storage device comprises a Double Data Rate (DDR) random access memory device. Example 12 includes the apparatus of example 11, wherein the DDR device comprises one of: a DDR2 device, a DDR3 device, a DDR4 device, a DDR5 device, or a DDR6 device.

Example 13 includes a system comprising: a processor coupled to a storage device; an interposer interface coupled between the processor and the storage device to allow a probe to capture one or more waveforms to be exchanged between the processor and the storage device; and a resistive network splitter to couple the interposer interface to the probe and the storage device, wherein the resistive network comprises a plurality of resistors, wherein the plurality of resistors is to reduce signal reflection.

Example 14 includes the system of example 13, wherein a value of each of the plurality of resistors is to be determined based at least in part on input and/or output transmission line impedances for the resistive network. Example 15 includes the system of example 13, wherein the value of each of the plurality of resistors is to be determined as a function of input and out transmission line impedances to reduce signal reflections. Example 16 includes the system of example 13, wherein the plurality of resistors comprises three resistors to form a three-way resistor split, wherein the value of each of the three resistors is to be determined to match an equivalent resistance of a split path looking toward and into the three-way resistor split.

Example 17 includes the system of example 13, wherein the plurality of resistors comprises a first resistor, a second resistor and a third resistor, wherein: the first resistor is to couple a resistive network junction to the processor, the second resistor is to couple the resistive network junction to the storage device, and the third resistor is to couple the resistive network junction to the probe. Example 18 includes the system of example 17, wherein the interposer interface is to couple the processor to a first end of the first resistor, wherein a second end of the first resistor is to couple to the resistive network junction. Example 19 includes the system of example 13, wherein one or more of the plurality of resistors comprise a surface mount resistor or an embedded resistor. Example 20 includes the system of example 13, wherein the processor comprises one or more processor cores. Example 21 includes the system of example 13, wherein the storage device comprises a dynamic random access memory device. Example 22 includes the system of example 13, wherein the storage device comprises a Double Data Rate (DDR) random access memory device.

Example 23 includes an apparatus comprising means to perform a method as set forth in any preceding example. Example 24 includes machine-readable storage including machine-readable instructions, when executed, to implement a method or realize an apparatus as set forth in any preceding example.

In various embodiments, the operations discussed herein, e.g., with reference to FIGS. 1 et seq., may be implemented as hardware (e.g., logic circuitry or more generally circuitry or circuit), software, firmware, or combinations thereof, which may be provided as a computer program product, e.g., including a tangible (e.g., non-transitory) machine-readable or computer-readable medium having stored thereon instructions (or software procedures) used to program a computer to perform a process discussed herein. The machine-readable medium may include a storage device such as those discussed with respect to FIGS. 1 et seq.

Additionally, such computer-readable media may be downloaded as a computer program product, wherein the program may be transferred from a remote computer (e.g., a server) to a requesting computer (e.g., a client) by way of data signals provided in a carrier wave or other propagation medium via a communication link (e.g., a bus, a modem, or a network connection).

Reference in the specification to “one embodiment” or “an embodiment” means that a particular feature, structure, and/or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although embodiments have been described in language specific to structural features and/or methodological acts, it is to be understood that claimed subject matter may not be limited to the specific features or acts described. Rather, the specific features and acts are disclosed as sample forms of implementing the claimed subject matter.

1. An apparatus comprising:
an interposer interface coupled between a first component and a second component to allow a probe to capture one or more waveforms to be exchanged between the first component and the second component; and
a resistive network splitter to couple the interposer interface to the probe and the second component,
wherein the resistive network comprises a plurality of resistors, wherein the plurality of resistors is to reduce signal reflection.

2. The apparatus of claim 1, wherein a value of each of the plurality of resistors is to be determined based at least in part on input and/or output transmission line impedances for the resistive network.

3. The apparatus of claim 1, wherein the value of each of the plurality of resistors is to be determined as a function of input and out transmission line impedances to reduce signal reflections.

4. The apparatus of claim 1, wherein the plurality of resistors comprises three resistors to form a three-way resistor split, wherein the value of each of the three resistors is to be determined to match an equivalent resistance of a split path looking toward and into the three-way resistor split.

5. The apparatus of claim 1, wherein the plurality of resistors comprises a first resistor, a second resistor and a third resistor, wherein: the first resistor is to couple a resistive network junction to the first component, the second resistor is to couple the resistive network junction to the second component, and the third resistor is to couple the resistive network junction to the probe.

6. The apparatus of claim 5, wherein the interposer interface is to couple the first component to a first end of the first resistor, wherein a second end of the first resistor is to couple to the resistive network junction.

7. The apparatus of claim 1, wherein one or more of the plurality of resistors comprise a surface mount resistor or an embedded resistor.

8. The apparatus of claim 1, wherein the first component comprises a processor having one or more processor cores.

9. The apparatus of claim 1, wherein the second component comprises a storage device.

10. The apparatus of claim 9, wherein the storage device comprises a dynamic random access memory device.

11. The apparatus of claim 9, wherein the storage device comprises a Double Data Rate (DDR) random access memory device.

12. The apparatus of claim 11, wherein the DDR device comprises one of: a DDR2 device, a DDR3 device, a DDR4 device, a DDR5 device, or a DDR6 device.

13. A system comprising:
a processor coupled to a storage device;
an interposer interface coupled between the processor and the storage device to allow a probe to capture one or more waveforms to be exchanged between the processor and the storage device; and
a resistive network splitter to couple the interposer interface to the probe and the storage device,
wherein the resistive network comprises a plurality of resistors, wherein the plurality of resistors is to reduce signal reflection.

14. The system of claim 13, wherein a value of each of the plurality of resistors is to be determined based at least in part on input and/or output transmission line impedances for the resistive network.

15. The system of claim 13, wherein the value of each of the plurality of resistors is to be determined as a function of input and out transmission line impedances to reduce signal reflections.

16. The system of claim 13, wherein the plurality of resistors comprises three resistors to form a three-way resistor split, wherein the value of each of the three resistors is to be determined to match an equivalent resistance of a split path looking toward and into the three-way resistor split.

17. The system of claim 13, wherein the plurality of resistors comprises a first resistor, a second resistor and a third resistor, wherein: the first resistor is to couple a resistive network junction to the processor, the second resistor is to couple the resistive network junction to the storage device, and the third resistor is to couple the resistive network junction to the probe.

18. The system of claim 17, wherein the interposer interface is to couple the processor to a first end of the first resistor, wherein a second end of the first resistor is to couple to the resistive network junction.

19. The system of claim 13, wherein one or more of the plurality of resistors comprise a surface mount resistor or an embedded resistor.

20. The system of claim 13, wherein the processor comprises one or more processor cores.

21. The system of claim 13, wherein the storage device comprises a dynamic random access memory device.

22. The system of claim 13, wherein the storage device comprises a Double Data Rate (DDR) random access memory device.
